(19) United States
(12) Patent Application Publication
(10) Pub. No.: US 2016/0045018 A1
(43) Pub. Date: Feb. 18, 2016

(54) UNIVERSAL RETAINING DEVICE FOR A MOBILE MULTIMEDIA TERMINAL

(71) Applicant: HEADFLAT GMBH, Malsch (DE)

(72) Inventor: Dirk Keune, Ettlingen (DE)

(73) Assignee: HEADFLAT GMBH, Karlsruhe (DE)

(21) Appl. No.: 14/763,294

(22) PCT Filed: Jan. 24, 2014
(86) PCT No.: PCT/EP2014/051431

§ 371 Date: Nov. 5, 2015

(30) Foreign Application Priority Data
Jan. 25, 2013 (DE) 202013000740.0

(51) Int. Cl. A45F 5/00; H05K 7/02

(52) U.S. Cl. CPC A45F 5/00; H05K 7/02; A45F 2005/002

(57) ABSTRACT

A retaining device for a mobile multimedia terminal, including: at least one retaining arm having first and second ends; retaining arrangement for fastening the retaining arm to substantially any commercially available headgear, are arranged at the first end; a receiving and retaining device for the multimedia terminal is located at the second end; the receiving and retaining device is arranged or adjustable in relation to the retaining arm such that at least the graphic display apparatus of a multimedia terminal received therein is substantially centered in the field of view of a user after the retaining arm has been fastened to the headgear. The retaining arrangement includes: at least two fastening arms that extend rearward from a fastening point at the first end of the retaining arm on a respective side of the headgear and interact with the headgear in a form or force-fitting fashion. At least one additional fastening element fixes the retaining arm with respect to the headgear.

### BACKGROUND

The invention relates to a retaining device for a mobile multimedia terminal, for example a pocket PC, a smartphone, or the like, for example without limiting the iPhone or the iPod touch from the company Apple.

Such multimedia terminals provide the user with a wide spectrum of audio and video content and are frequently used already as a kind of television replacement. Additionally, the above-mentioned multimedia terminals serve also as game consoles, with increasingly here control effects based on motion and acceleration sensors being used. Via integrated (wireless) communication means, the multimedia terminals can also be connected to other electronic devices and cooperate with them.

In particular in case of extended use, here it is however considered disadvantageous that the user must constantly hold the respective multimedia terminal at a position of his/her viewing range, with is uncomfortable on the long term, which leads to an unpleasant stress and/or tiring and hardening of the arm muscles. Additionally, the above-mentioned use of the mobile multimedia terminal leads to the circumstance that here the user potentially has maximally only one hand available for an extended period of time to perform other daily activities on the side.

When the above-mentioned multimedia terminals are used as game consoles it would additionally be beneficial if the user has his/her hands free in order to allow handling a respectively connected additional control device, such as an operating console, or an additional game piece, such as a pistol, a racket, or the like.

With regards to the first mentioned applications, help can be provided in that the mobile multimedia terminal is placed in a suitable fashion onto an object, such as a pillow or the like. However, this requires the availability of such an appropriate object, which particularly in mobile use is not necessarily given. Additionally, such a solution requires a relatively static sitting or inclined position of the user, which is undesired on the mid or long term. Additionally it has shown that putting down or placing the mobile multimedia terminal, particularly on a pillow, can negatively influence the quality of the audio signal, when for example the integrated speaker of the device is partially or entirely covered.

A generic retaining device, which is particularly suited also for applications in which the multimedia terminal is used for gaming, is known from EP 2 103 862 A1.

US 2004/008157 A1 discloses a monocular video-audio display fastened to a cap, which comprises a focusing mechanism and an eye cup, and which therefore must be arranged directly in front of the eye of the user.

From U.S. Pat. No. 6,392,798 B1 a device is known for holding visual aid devices at the eye level, with relatively heavy visual aid devices, such as binoculars, video cameras, or photo cameras being arranged directly in front of the eye of the user. For this purpose, the device of prior art shows a recess for accommodating the nose of the user in order to allow arranging the respective device directly in front of the eyes of the user. The actual retaining apparatus for the visual aid device is fastened in a pivotally articulate fashion, for example in the temple area at a head band designed particularly for this purpose.

US 2003/122958 A1 discloses a thermal imaging unit for firefighters or first responders, in which a single ocular lens is directly arranged in front of the protective mask and one eye of the user/carrier.

A fastening device is known from U.S. Pat. No. 6,247,205 B1, which should allow the use of a binocular without the hands being involved. For this purpose, a clamping device is provided, which is connected to the binocular and clamped at the visor of a cap such that the binocular is located directly in front of the eyes of the user.

US 2009/00060473 A1 discloses a flexible retaining arm for a multimedia terminal which is to be fastened via a clamping mechanism at a bicycle helmet, among other things.

### SUMMARY

The invention is based on the objective to provide a retaining device for a mobile multimedia terminal, avoiding the above-discussed disadvantages, which is suitable for daily use based on its simple and cost-effective embodiment and which allows the user particularly to use the video functions of his/her multimedia terminal over an extended period of time without tiring and without here being adversely affected in his/her manual options and/or the enjoyment of the audio function of the device. Furthermore, the mobility of the multimedia terminal shall be essentially unaffected, so that the multimedia terminal can still be used for gaming. Here, the retaining device shall be embodied such that it can be used with quasi arbitrary commercial headgears and thus it can be marketed as a separate article, particularly as an accessory for existing products, such as toys or the like.

The invention attains this objective in a retaining device for a multimedia terminal including one or more of the features of the invention.

Advantageous further developments of the invention are the objective of dependent claims, with their wording is hereby explicitly included in the description by way of reference.

According to the invention, a retaining device for a mobile multimedia terminal, such as a pocket PC, a smartphone, or the like is embodied as follows: It comprises at least one retaining arm with a first and a second end; it further comprises fastening means for fastening the retaining arm at an essentially commercial headgear, which headgear may represent for example a baseball cap or a headband with a visor and/or sun shield. Here it is provided that the retaining arm extends from the headgear towards the front, seen in the direction of view of the user, with the above-mentioned fastening means being arranged at a first end of the retaining arm. Receiving and fastening means for the multimedia terminal are provided at the other, second end of the retaining arm. In the retaining device according to the invention the receiving and retaining means for the multimedia terminal are arranged and/or adjustable in reference to the retaining arm such that upon fastening of the retaining arm at the headgear via the fastening means at least the graphic display device (the monitor) of a multimedia terminal received therein is located essentially in the middle of the viewing area of the user. The fastening means according to the invention include at least two fastening arms, which are embodied and equipped for the purpose of extending towards the rear at one respective side of the headgear, starting from a preferably common retaining point at the first end of the retaining arm, with the fastening arms cooperating in a form-fitting and/or force-fitting fashion with the headgear. Furthermore, the fastening means comprise at least one additional fastening element, which is embodied and provided to fix the fastening arm in reference to the headgear, preferably with regards to up and down movements and/or lateral motions, most preferably in the area of a visor or a shield of the headgear.

According to the underlying idea of the present invention the suggested retaining device also comprises at least one retaining arm to be fastened to a headgear.

The retaining arm is fastened at one of its ends to the headgear and carries at its other end the above-mentioned recesses and retaining means for the multimedia terminal, by which ultimately the retaining arm is connected. The multimedia terminal itself is not a part of this invention. In general, any commercially available multimedia terminal is suitable for use with the retaining device according to the invention. Here, low weight is advantageous.

As already explained, the retaining arm of the retaining device according to the invention extends, after its fastening to the headgear, in the direction of view of the user towards the front, and the receiving and retaining means for the multimedia terminal are arranged and/or appropriately adjustable at the front end of the retaining arm such that subsequently the display of the multimedia terminal is located approximately in the center of the viewing area of the user so that this above-mentioned display can easily be viewed with a relaxed positioning of the head and without using any hands.

A first further development of the retaining device according to the invention provides that a connection element is provided at the fastening site, which connection element connects the two fastening arms and the retaining arm to each other. Preferably the connection is embodied in a detachable fashion, for example by a threaded element or a plug-in connection being used here, without the invention being limited to the use of such connections. This way, the particular advantage develops that after the release of the connection element the two retaining arms on the one side and the retaining arm on the other side can be separated from each other, allowing the space required for the fastening device to be reduced, for example for packaging purposes.

Another further development of the retaining device according to the invention provides that the two fastening arms are embodied as separate components. This way the retaining device can be disassembled into the two fastening arms and the retaining arm, which further reduces the required space. The two fastening arms can intersect each other like scissors, preferably approximately at the fastening point and from here extend further towards the front, with here simultaneously forming two retaining arms for receiving and retaining means and/or for the multimedia terminal.

When furthermore the receiving and retaining means can be connected to the second end of the retaining arm and/or the retaining arms in a detachable fashion, particularly also via suitable threaded or plug-in connection (without limitation thereto), as provided in another further development of the retaining device according to the invention, an even further possibility for disassembly of the retaining device results with accordingly further reduced space requirements.

An alternative further development of the retaining device according to the invention provides that the two fastening arms are embodied in one piece. Although here perhaps the space required may be slightly increased, however a particularly simple embodiment of the retaining device results due to the lower number of individual components.

Furthermore, in a one-piece embodiment of the two fastening arms it can be achieved that they must be slightly moved apart from each other when mounting the retaining device at a headgear, causing a certain pre-stressing to be generated, which subsequently serves to laterally fix the retaining device at the headgear in a force-fitting fashion.

Another further development of the retaining device according to the invention provides that the two fastening arms, on the one side, and the retaining arm, on the other side, each exhibit at least one penetration, through which penetration the above-mentioned connection element can be guided, for example like a bolt with a nut, in order to connect the two fastening arms and the retaining arm. This way, the various components can be connected in a particularly simple fashion to a retaining device according to the invention.

Another further development of the retaining device according to the invention provides that the fastening arms show at their free ends fastening structures for the form-fitting and/or force-fitting cooperation with a headgear. These fastening structures may be embodied as clamping structures, which preferably cooperate in a clamping fashion with a brim of the headgear, most preferred by laterally encompassing said brim.

The invention is however not limited to a clamping connection between the retaining device and the headgear, although here the particular advantage develops that substantially any commercially available headgear, particularly a headband or a baseball cap, can be equipped with such a retaining device. Additionally or alternatively it is however possible, for example, to provide the fastening arms of the retaining device with suitable Velcro means, pushbuttons, magnetic elements, or the like, which cooperate with respective counterparts at the headgear in a form-fitting and/or force-fitting fashion. In this context, the retaining device and/or its construction set may comprise the respective counterparts, which then must be fastened at a conventional headgear. Alternatively, an already appropriately equipped headgear may be provided together with the retaining device.

A particularly preferred further development of the retaining device according to the invention provides that at least one fastening arm comprises at its free end two clamping elements, essentially extending parallel in reference to each other and at a certain distance from each other, which preferably are formed in one piece with the remaining fastening arm. The brim of a conventional headgear can be inserted and/or clamped between these clamping elements in order to fasten the retaining device at a headgear.

Preferably the retaining device is suitable for the use with a conventional baseball cap, with the retaining arms projecting from the lateral cap area towards the front to a preferably central position above the visor of the cap. Here, preferably the already discussed fastening site is provided, from which the retaining arm projects towards the front. This offers the particular advantage that the retaining device can rest in the area of the fastening site from the top on the visor, while further back it cooperates in the described fashion in a form-fitting and/or force-fitting manner with the headgear in order to compensate the weight of the multimedia terminal.

Another preferred further development of the retaining device according to the invention provides that the fastening element can be connected to the retaining arm in a detachable fashion. Here, the fastening element may be embodied like a threaded element or like a plug-in connector. The above-mentioned detachable invention occurs preferably in the area of an appropriate additional penetration of the retaining arm.

As already discussed, the fastening element serves to fix the retaining arm in another fastening site in reference to the headgear. When the fastening element is connected in a detachable fashion to the retaining arm as described, the retaining device can easily be adjusted to different headgears. In this context, several penetrations or an oblong hole may be provided at the retaining arm as well, so that accordingly several adjustment options develop.

Most preferred, the retaining element comprises an angular part, which is embodied and provided to engage the visor of the headgear from below, preferably from the front. By the option for adjustments discussed above, here the fastening element can easily be adjusted to differently long visors.

An extremely preferred further development of the retaining device according to the invention provides in this context that the fastening element is displaceable along the retaining arm, preferably within a longitudinal recess like an oblong hole provided for this purpose at the retaining arm, as already discussed.

The invention is however not limited in any way to the above-described types of fastening elements. In general, it is also possible that the fastening element is embodied to cooperate otherwise in a form-fitting and/or force-fitting manner with the headgear, particularly a visor of a cap. In particular, in this context magnetic elements, Velcro connections, pushbuttons, or the like may be provided, which on the one side were to be arranged at the retaining arm and on the other side at the headgear. In this context, the headgear would be suitably equipped, with reference being made to the statements rendered above in this context, in order to avoid repetitive text.

It is particularly preferred for at least one of the elements retaining arm, fastening arm, fastening element, fastening structures, and connection element, preferably even several or all of these elements, being made from or comprising plastic, allowing to achieve a particularly light and cost-effective embodiment of the retaining device.

In order to allow the multimedia experience to be sufficiently pleasant, in light of the presently common dimensions of typical multimedia terminals, such as iPhones or iPod touch from the company Apple, a first further development of the retaining device according to the invention provides that the retaining arm, preferably when realizing suitable adjustment options, particularly an extension or shortening, is embodied such that the receiving and retaining means for the multimedia terminal are located at a distance from the eye of the user ranging from 10 to 40 cm, preferably from 15 cm to 30 cm.

Independent therefrom, in another further development the retaining device may also exhibit two or more essentially identical retaining arms, arranged parallel, with the receiving and retaining means for the multimedia terminal being arranged at their respectively second ends, in order to improve the stability of the arrangement. In this context two (or more) fastening points may be provided to connect the retaining arms to the fastening means.

Another further development of the retaining device according to the invention provides that the receiving and retaining means for the multimedia terminal are fastened at the retaining arm in an articulate fashion in order to allow a wide range of optional adjustments for orientation of the display device of the multimedia terminal. In this context, for example the use of a ball joint or a pivoting joint may be provided between the retaining arm or the above-mentioned receiving and retaining means. Alternatively, the retaining arm and the receiving/retaining means may be embodied in one piece.

Advantageously the receiving and retaining means are embodied as a retaining cup, in which the multimedia terminal can be laterally inserted and/or clipped. For various types of multimedia terminals respectively separate receiving and retaining means may be provided, which are sized according to the dimensions of the multimedia terminal. Alternatively, the receiving and retaining means may be embodied in the form of several retaining projections, preferably arranged in the Y or X geometry.

Alternatively, it may however also be provided that the receiving and retaining means for the multimedia terminal are adjustable to differently sized multimedia terminals.

In this context it may be provided that the receiving and retaining means exhibit clamping means for the lateral clamping of the multimedia terminal, which clamping means can be adjusted and fixed in reference to each other at a suitable distance.

Furthermore it may be provided that the receiving and retaining means are embodied as elastic means for clamping the multimedia terminal.

Alternatively it may be provided that the receiving and retaining means are embodied like an elastic, preferably rubber-like casing, with said casing being able to receive the multimedia terminal in a force-fitting and/or form-fitting fashion so that a display of the multimedia terminal essentially remains clear.

Furthermore, the receiving and retaining means for the multimedia terminal may be fastened at the retaining arm in a detachable fashion, which has already been pointed out, with in this context particularly the use of a threaded connection, a plug-in connection, a clamping connection, or a clip connection being considered. However, the present invention also includes embodiments in which the above-mentioned receiving and retaining means and at least one retaining arm are connected to each other in one piece, in a material-to-material, or in another fashion.

In order to achieve a particularly compact and simply designed embodiment of the retaining device according to the invention it is however preferred that precisely one retaining arm is provided which is essentially embodied stiffly, straight, and flat, and made from a plastic material. The latter applies preferably in general also for the fastening means as well as the receiving and retaining means.

Additionally, within the scope of another embodiment of the present invention, at least one retaining arm may have a joint so that the receiving and retaining means for the multimedia terminal, when necessary, can be moved (pivoted) out of the viewing area of the user.

Another further development of the retaining device according to the invention provides that the retaining arm is embodied at least sectionally in a flexible fashion, preferably bendable, but semi-stiffly, like a gooseneck or the like. This way, as well, an appropriate positioning of the multimedia terminal can be achieved.

It is not necessary for the at least one retaining arm to be embodied in a straight fashion, but within the scope of appropriate further developments of the present invention it may exhibit in the area of its second end at least one angle or bend in order to position the receiving and retaining means for the multimedia terminal already in the desired fashion in the viewing area of the user. Here, the degree of the angle and/or bend may range preferably from 70° to 110°, most preferred amounting to approximately 90°.

According to the invention the fastening means, as already mentioned, may also be partially embodied in the form of a Velcro connection or the like, with for example a suitable hook material that is arranged on the retaining arm, particularly adhered thereto, while the respective mesh material is located at the headgear. Of course the inverse arrangement is also possible.

It is common for all embodiments of the retaining device according to the invention that they furthermore may comprise a speaker device or a so-called sound system, which preferably is embodied like headphones, with the speaker device preferably cooperating with the multimedia terminal, using signal technology, in order to provide audio signals of the multimedia terminal.

### BRIEF DESCRIPTION OF THE DRAWINGS

Additional features and advantages of the present invention are discernible from the following description of exemplary embodiments based on the drawings.

FIGS. 1a and 1b show an embodiment of the retaining device according to the invention upon fastening on a conventional headgear;

FIG. 2 shows the retaining device according to FIGS. 1a and 1b in the disassembled state from the side;

FIG. 3 shows the retaining device according to FIG. 2 in a top view;

FIG. 4 shows the retaining device according to FIG. 1a and FIG. 1b in a top view;

FIG. 5 shows the retaining device of FIG. 4 from the bottom;

FIG. 6 shows an illustration according to FIG. 3 in a view from the bottom;

FIGS. 7a and 7b show another embodiment of the retaining device according to the invention in the assembled and disassembled state;

FIGS. 8a and 8b show another embodiment of the retaining device according to the invention in the assembled and disassembled state;

FIG. 9 shows a first embodiment of the receiving and retaining means;

FIG. 10 shows a second embodiment of the receiving and retaining means;

FIG. 11 shows a third embodiment of the receiving and retaining means; and

FIG. 12 shows a fourth embodiment of the receiving and retaining mean.

### DETAILED DESCRIPTION OF THE PREFERRED EMBODIMENTS

In all figures, identical reference characters relate to identical elements or at least ones with identical functions.

The retaining device in its entirety is marked with the reference character 1 in the figures. It serves to fasten a multimedia terminal 2, such as a smartphone or the like, to a conventional headgear 3, which is embodied like a headband with a visor 3a, such that the user, not shown, can perform even fast (head) movements without losing the multimedia terminal 2. For this purpose, the retaining device 1 comprises a retaining arm 4, which extends in the intended use of the retaining device 1 from the headgear 3 away towards the front. At a front end 4a of the retaining arm 4, which in the present case is also called the second end, receiving and retaining means 6 are arranged for the multimedia terminal 2, while at the other end 4b of the retaining arm 4, which in the present case is also called the first end, fastening means 5 are provided serving to connect the retaining arm 4 and/or the retaining device 1 overall to the headgear 3, which is discussed in greater detail in the following.

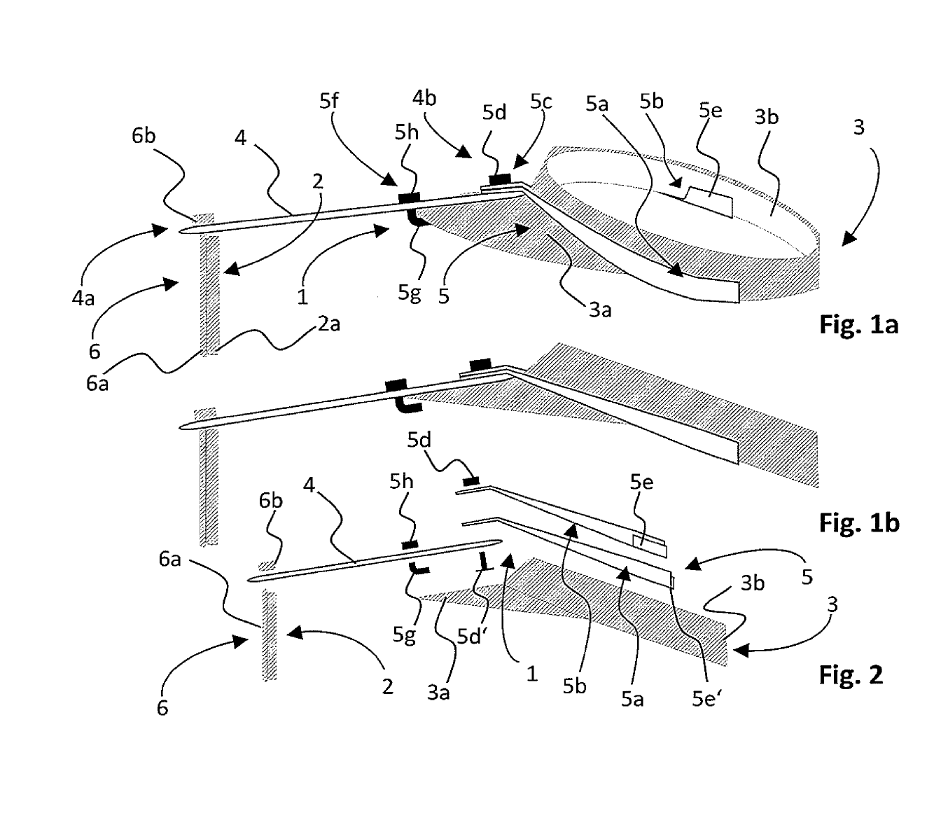

The fastening means 5 initially comprises two fastening arms 5a, 5b, which respectively extend laterally in reference to the headgear 3 and/or the head of the user (not shown) from the (forehead) area above the visor 3a to approximately an area above the ear. Due to the illustration selected, in FIG. 1a only one fastening arm 5a is shown in its entirety, while the other fastening arm 5b being essentially covered by the headgear 3. The two fastening arms 5a, 5b are connected at a common fastening point 5c to the retaining arm 4, with here a threaded element 5d is provided for that purpose, which extends through aligned penetrations in the fastening arms 5a, 5b on the one side and the retaining arm 4 on the other side in order to connect the above-mentioned elements in a force-fitting fashion. At their free ends, the fastening arms 5a, 5b show clamping elements 5e, with only one of them being discernible here, which cooperate in a clamping fashion with the brim 3b of the headgear 3, which is discussed in greater detail in the following.

The reference character 5f marks an additional fastening element, which serves to fix the retaining arm 4 at another point with regards to the headgear 3, in the present case the visor 3a. The above-mentioned retaining element 5f comprises an angled part 5g, which engages underneath the sun visor 3a from the front and which is connected and/or can be connected via a threaded means 5h or the like to the retaining arm 4 in a detachable fashion. This way, the retaining element 1 can be adjusted to different headgears 3, particularly differently long visors A.

Furthermore, the reference character 2a indicates in FIG. 1a the display of the multimedia terminal 2, which in the manner shown is located approximately in the middle of the viewing area of the user. The length of the retaining arm 4 is selected preferably from 10 to 40 cm, most preferred ranging from 15 to 30 cm, so that a most relaxed viewing of the display 2a is possible, with it here assuming a sufficiently large portion of the viewing area.

The reference character 6a indicates a retaining cup or an arrangement of retaining projections of the receiving and retaining means 6, with the multimedia terminal 2 being securely accepted therein. Preferably the element 6a and accordingly the receiving and retaining means overall are detachably connected to the retaining arm 4, for example via a suitable threaded or plug-in connection 6b.

Preferably all of the above-mentioned components of the retaining device 1 are made from plastic, most preferably however at least the retaining arm 4 and the fastening arms 5a, 5b.

While FIG. 1a shows the retaining device 1 together with the multimedia terminal 2 and the headgear 3 in a slightly perspective illustration, the same elements are shown in FIG. 1b in a side view. In order to prevent overloading the graphic illustration, in FIG. 1b the reference characters were omitted; however they are easily discernible from the illustration of FIG. 1.

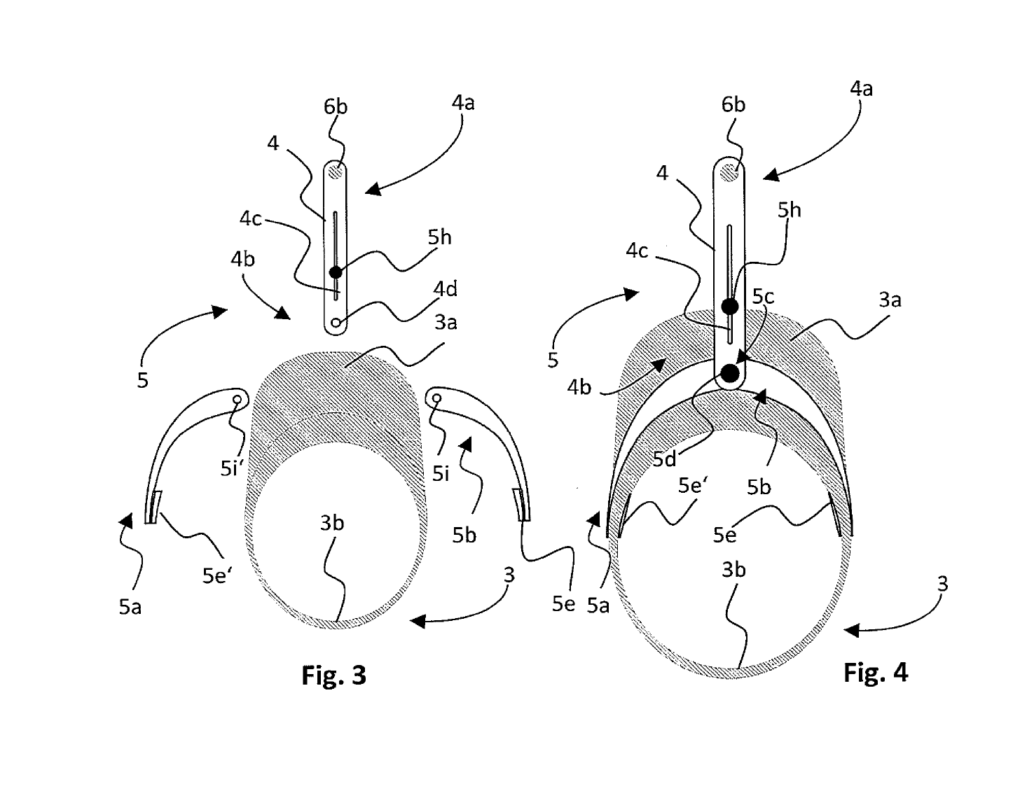

FIG. 2 shows the same retaining device 1 as FIGS. 1a and 1b, however in a disassembled state in which the retaining device 1 is disassembled into its individual components and particularly separated from the headgear 3.

Accordingly, in FIG. 2 both fastening arms 5a, 5b are easily discernible. The above-mentioned clamping elements are provided at both fastening arms 5a, 5b, which in FIG. 2 are marked with the reference characters 5e and 5e′, respectively. The embodiment of the receiving and retaining means 6 is further discernible from FIG. 2, detachable from the retaining arm 4, which has already been pointed out.

Additionally, the required counterpart 5d′ for the element 5d is also discernible from FIG. 2, with the elements 5d, 5d′ jointly serving for the detachable, force-fitting connection of the retaining arms 5a, 5b to the retaining arm 4.

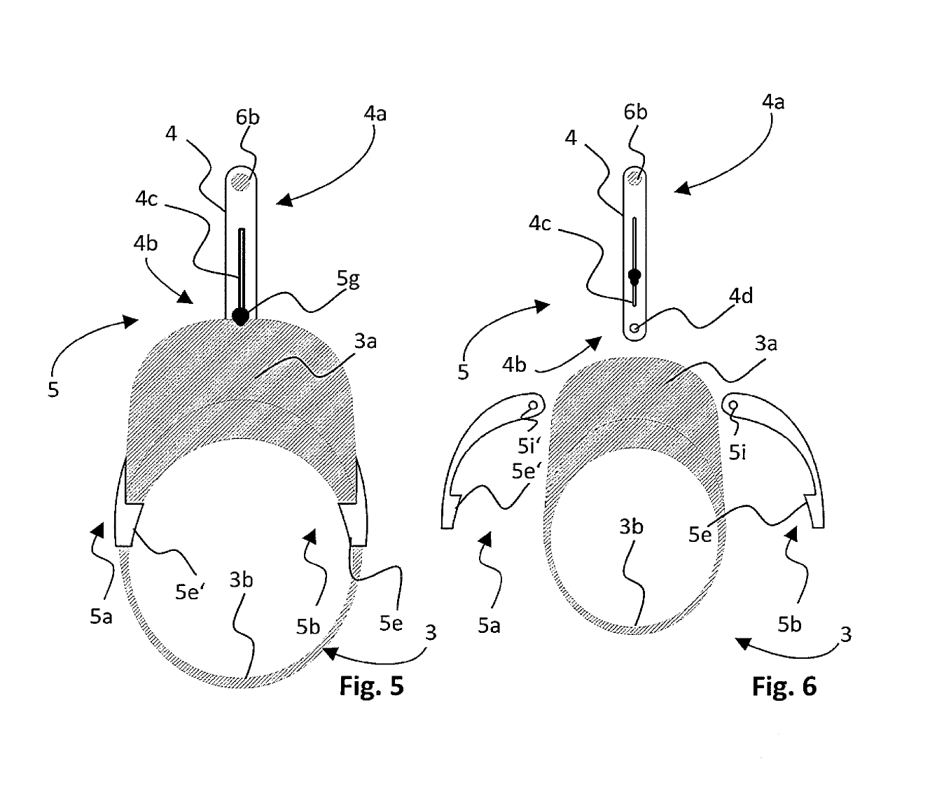

The following FIGS. 3 to 5 show various views of the same retaining device 1 in a top view (FIGS. 3 and 4) as well as in a view from the bottom (FIGS. 5 and 6). In the following, primarily the respectively also discernible features of the retaining device 1 are explained in greater detail, which were not visible in the illustrations of FIGS. 1a to 2.

In FIGS. 3 and 4 at least the retaining means 5 of the retaining device are discernible as well as the headgear 3 in the plan view, i.e. from the top. FIG. 3 shows a disassembled state of the retaining device and/or the retaining means 5, while FIG. 4 shows a finished assembled state of the device and/or the retaining means 5, in which the fastening means 5 and the headgear 3 are connected.

The embodiment of the fastening arms 5a, 5b at their respectively free ends (clamping elements 5e and 5e′, respectively) are clearly discernible particularly in FIG. 3. The above-mentioned clamping elements 5e, 5e′ are embodied such that another element extends essentially parallel to one end of the respective fastening arm 5a, 5b, with a certain clearance or distance remaining between the end of the fastening arm 5a, 5b and said element, which is suitable to accept the brim 3b of the headgear 3 in a clamping fashion, which is particularly clearly shown in FIG. 4. Preferably the entire element is embodied in one piece at the end of the fastening arms 5a, 5b with the remaining fastening arm 5a, 5b in order to this way in a simple fashion generating the clamping elements 5e, 5e′.

FIG. 3 shows additionally corresponding penetrations both in the fastening arms 5a, 5b as well as the retaining arm 4 at its end 4b. In FIG. 3 the above-mentioned penetrations are marked with the reference character 4d and/or 5i, 5i′. They serve to accept the connection elements 5d at the fastening site 5c (cf. e.g., FIG. 4), which has already been pointed out.

As furthermore discernible both from FIG. 3 as well as from FIG. 4, the retaining arm 4 comprises in the direction of its longitudinal extension an oblong embodied penetration 4c like a long hole, in which the additional fastening element 5f and/or 5g, 5h (cf. FIG. 1a and FIG. 2) are displaceable in order to adjust the fastening element according to FIG. 4 or FIG. 1a to the dimensions of the headgear 3, particularly in the area of the sun visor 3a, which has already been pointed out.

For reasons of clarity, from the receiving and retaining means 6 (cf. FIG. 1a) only the already described element 6b is explicitly shown in the FIGS. 3 and 4.

As furthermore discernible from FIGS. 3 and 4, the retaining arms 5a, 5b are preferably curved and embodied in a bendable fashion and largely assume the shape of the headgear 3 in the area of the sun visor 3a in order to achieve a flat contacting. In the area of the clamping elements 5e, 5e′ the retaining arms 5a, 5b engage under the brim 3b of the headgear 3 in the manner shown or encompass it, in order to ensure safe fastening in this area. Additionally, the retaining device rests in the manner already described on the visor or shield 3a of the headgear 3, and is particularly fixed with regards to up and down motions at the reference character 5h.

FIGS. 5 and 6 show an illustration of the above-described aspect similar to FIGS. 3 and 4, however in a view from the bottom. It is not necessary to discuss this matter in greater detail, here.

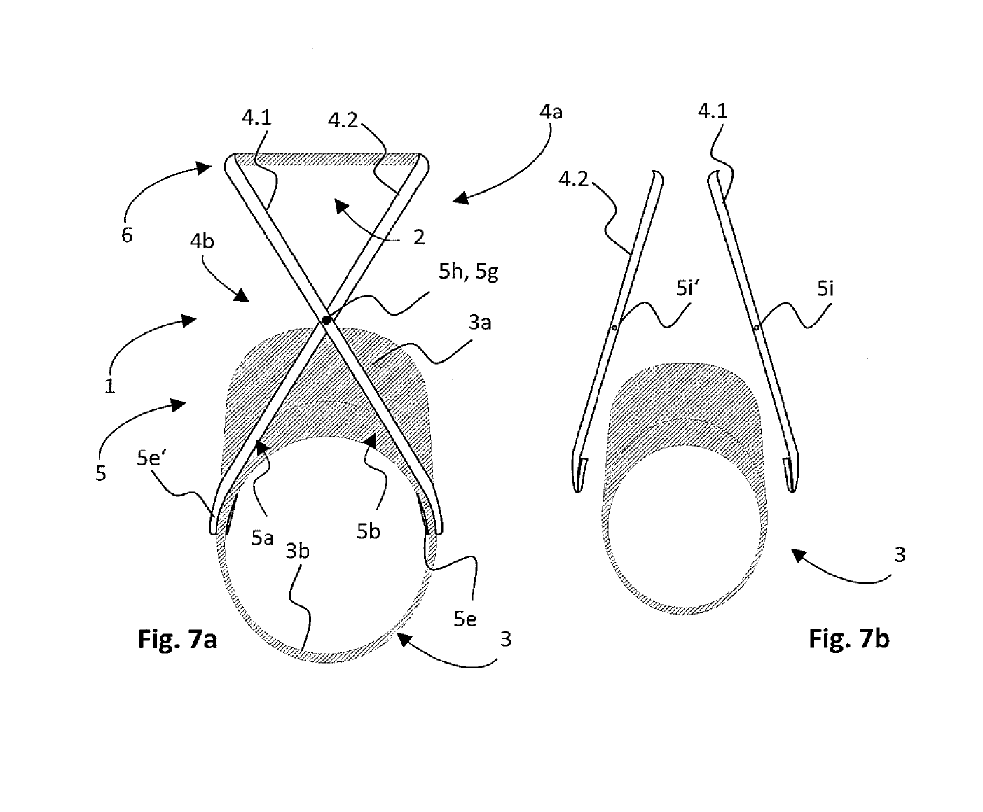

FIGS. 7a and 7b show another embodiment of the retaining device 1 according to the invention with fastening means 5, receiving and retaining means 6, as well as a terminal 2 symbolically indicated. Identical reference characters indicate here, as in all figures, identical elements or those serving identical functions.

According to FIG. 7a the two fastening arms 5a, 5b each extend straight forward, so that they intersect at the reference character 5h, 5g at the location of the additional fastening element (reference character 5f, cf. FIG. 1), and from here extend towards the front in two scissor-like retaining arms 4.1, 4.2 with increasing distance from each other. At the frontal end 4a of the arrangement, in the manner sketched, the receiving and retaining means 6 for the mobile terminal 2 are arranged, with the precise embodiment of the receiving and retaining means 6, not being discussed in greater detail, here. The fastening means 5 engage with the rear ends of the fastening arms 5a, 5b the brim 3d of the headgear 3 from behind (clamping elements 5e, 5e′; cf. FIG. 1a).

FIG. 7b shows the arrangement according to FIG. 7a in the disassembled state.

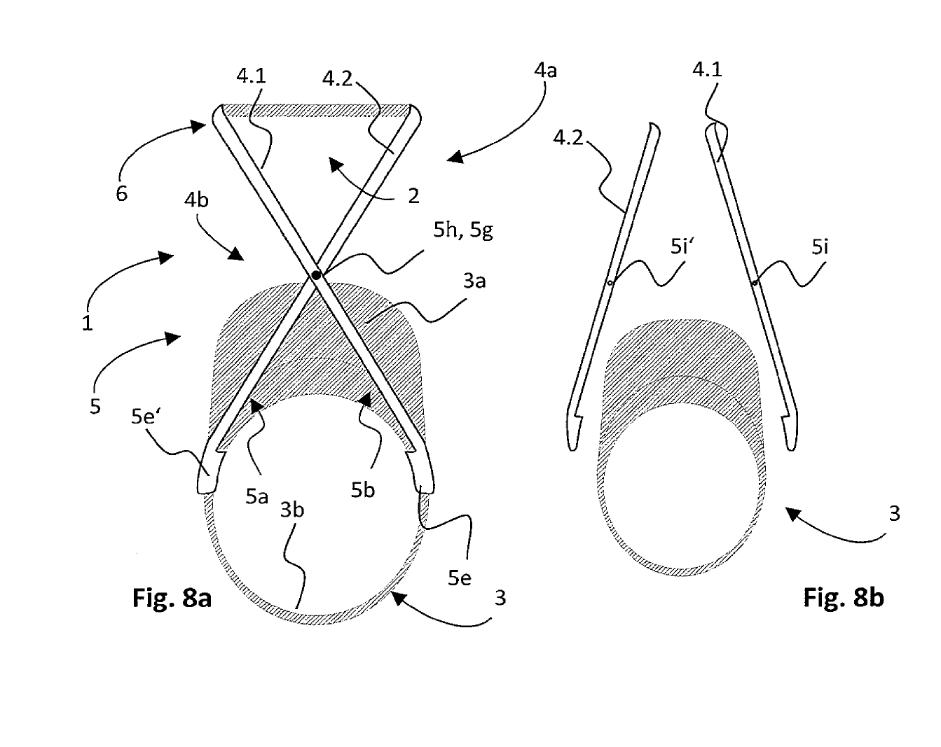

The embodiment according to FIGS. 8a, 8b is largely equivalent to the one in FIGS. 7a, 7b, with the difference that according to FIG. 8a the fastening arms 5a, 5b engage the brim 3d of the headgear 3 from the top. In general, such a variation is also possible for the objects of FIGS. 1a to 6.

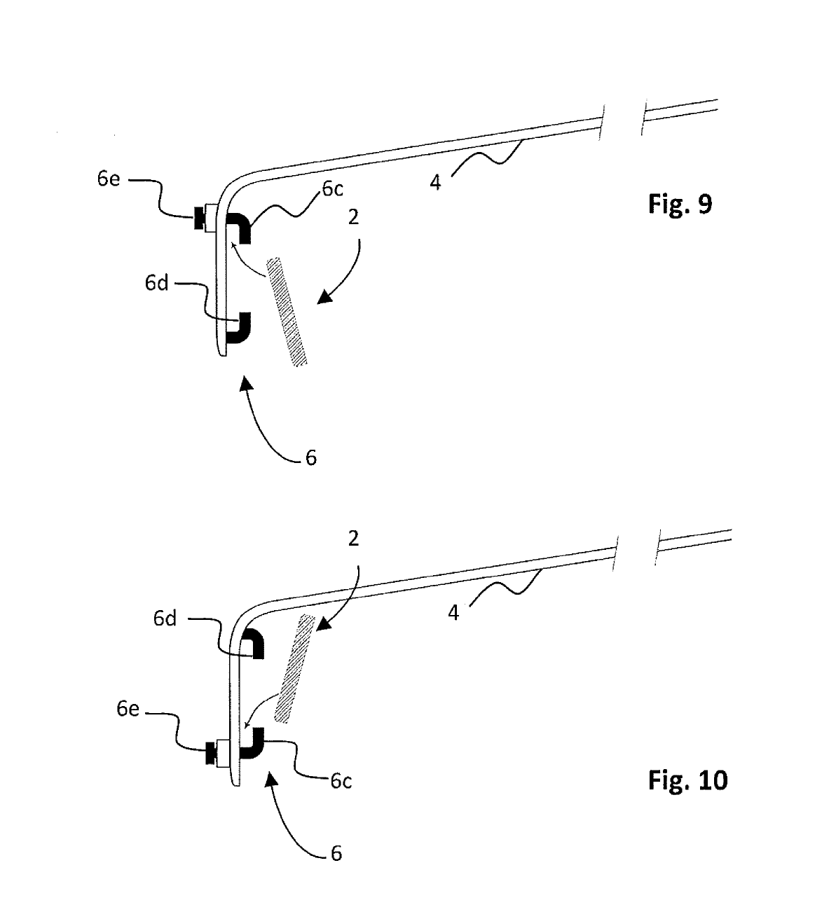

FIGS. 9 to 12 show additional embodiments of the receiving and retaining means 6 for the multimedia terminal 2, which preferably may be used with a single retaining arm 4. The invention is however not limited thereto; in general the receiving and retaining means 6 shown may also be used for the variants according to FIGS. 7a to 8b, if appropriate adapters (not shown) are used to preferably connect the respective receiving and retaining means 6 in a detachable fashion to the retaining arms 4.1, 4.2 (cf. FIGS. 7a to 8b).

According to FIG. 9, the receiving and retaining means 6 show two hook-like bent and/or angled clamping means 6c, 6d, with the clamping means 6c being embodied in an articular fashion in reference to the other clamping means 6d. A locking means 6e at the articulate clamping means 6c serves for the fixation thereof in reference to the other clamping means 6d, in order to hold the terminal 2 in a form-fitting fashion, as indicated.

According to FIG. 10, the clamping means, different from the one in FIG. 9, is embodied in an articulate and lockable fashion.

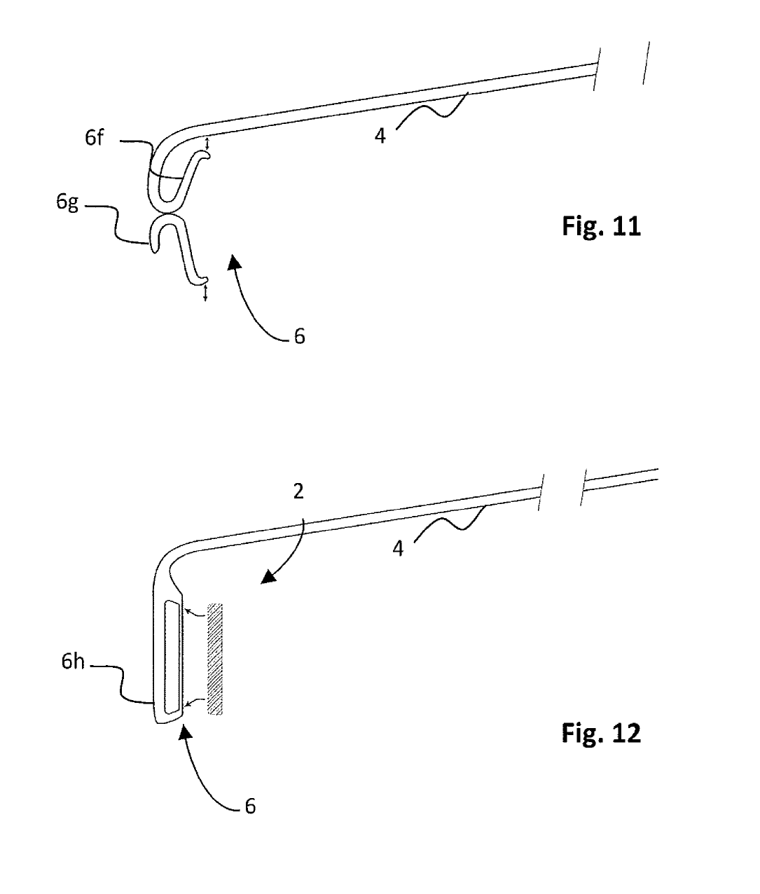

The receiving and retaining means 6 according to FIG. 11 are embodied as elastic means and comprise two spring arms 6f, 6g, which are connected to each other in an articulate fashion and can be opened by pressing against their rear ends, shown at the left in FIG. 11, similar to clothes pins in order to clamp a multimedia terminal (not shown).

The receiving and retaining means 6 according to FIG. 12 are embodied like a soft-rubber casing 6h, into which the terminal 2 is forced under deformation of the receiving and retaining means 6 and in which it is then held in a force-fitting and form-fitting fashion. This principle is known per se, for example from protective covers for smartphones or the like.

1. A retaining device (1) for a mobile multimedia terminal (2), comprising:
at least one retaining arm (4) with a first end (4b) and with a second end (4a);
retaining means (5) for fastening the retaining arm (4) on to a headgear (3) so that the retaining arm (4) extends from the headgear (3) in a viewing direction of a user towards a front, said retaining means (5) are arranged at the first end (4b) of the retaining arm (4);
receiving and retaining means (6) for the multimedia terminal (2) arranged at the other, second end (4a) of the retaining arm (4);
wherein the receiving and retaining means (6) for the multimedia terminal (2) are arranged or adjustable in reference to the retaining arm (4) such that at least a graphic display unit (2a) of the mobile multimedia terminal (2) accepted therein, after fastening the retaining arm (4) on to the headgear (3), is located essentially in a center of a user viewing area,
the retaining means (5) comprise:
two fastening arms (5a, 5b) extending towards a rear at one respective side, starting at a fastening site (5c) at one end (4b) of the retaining arm (4), and cooperating with the headgear (3) in at least one of a form-fitting or force-fitting fashion; and
at least one additional fastening element (5f) that fixes the retaining arm (4) in reference to the headgear (3) with respect to at least one of up and down motions or lateral motions.

2. The retaining device (1) according to claim 1, wherein a connection element (5d, 5d′) is provided at the fastening site (5c), which connects the two fastening arms (5a, 5b) and the retaining arm (4) with each other.

3. The retaining device (1) according to claim 2, wherein the two fastening arms (5a, 5b) and the at least one retaining arm (4) each comprise at least one penetration (4d, 5i, 5i′) for guiding the connection element (5d, 5d′) therethrough.

4. The retaining device (1) according to claim 1, wherein the two fastening arms (5a, 5b) are embodied in one piece.

5. The retaining device (1) according to claim 1, wherein the two fastening arms (5a, 5b) are embodied as separate components, which intersect at the fastening site (5c) and from two of the retaining arms (4.1, 4.2) where they extend towards the front.

6. The retaining device (1) according to claim 1, wherein the fastening arms (5a, 5b) include free ends that comprise fastening structures (5e, 5e′) for the at least of or the form-fitting or force-fitting cooperation with the headgear (3), said fastening structures being embodied as clamping structures, which are adapted to clamp with a brim (3b) of the headgear (3).

7. The retaining device (1) according to claim 6, wherein at least one of the fastening arms (5a, 5b) at the free end thereof comprises clamping elements (5e, 5e′) extending essentially parallel and at a distance from each other.

8. The retaining device (1) according to claim 1, wherein the at least one additional fastening element (5f) is embodied and provided to cooperate in at least one of a force-fitting or form-fitting fashion with a visor (3a) of the headgear (3).

9. The retaining device (1) according to claim 8, wherein the at least one additional fastening element (5f) is connectable in a detachable fashion to the retaining arm (4).

10. The retaining device (1) according to claim wherein the at least one additional fastening element (5f) comprises an angular part (5g), which is embodied and provided to engage under the visor (3a) of the headgear (3).

11. The retaining device (1) according to claim 1, wherein the at least one additional fastening element (5f) is longitudinally displaceable along the retaining arm (4).

12. The retaining device (1) according to claim 2, wherein at least one of the retaining arm (4), the fastening arms (5a, 5b), the connection element (5d, 5d′), the fastening structures (5e, 50, or the fastening element (5f) are made from plastic.

13. The retaining device (1) according to claim 1, wherein the receiving and retaining means (6) is connected in a detachable fashion to the second end (4a) of the retaining arm (4).

14. The retaining device (1) according to claim 1, wherein the retaining arm (4) is embodied such that the receiving and retaining means (6) for the multimedia terminal (2) is adapted to be located at a distance from 10 cm to 40 cm from an eye of a user.

15. The retaining device (1) according to claim 1, wherein the retaining arm (4) is embodied at least sectionally essentially flat.

16. The retaining device (1) according to claim 1, wherein at least one penetration is provided in the retaining arm (4), a fastening part is guided through the penetration which cooperates with at least one complementary structure of the headgear (3), in order to fix the retaining arm (4) in reference to the headgear (3).

17. The retaining device (1) according to claim 1, further comprising a speaker system that cooperates with the mobile multimedia terminal (2) to receive an audio signal.

18. The retaining device (1) according to claim 1, wherein the receiving and retaining means (6) for the multimedia terminal (2) is adjustable to differently sized multimedia terminals.

19. The retaining device (1) according to claim 18, wherein the receiving and retaining means (6) comprise clamping means (6c, 6d) for the lateral clamping of the multimedia terminal (2), said clamping means (6c, 6d) are adjustable in reference to each other to a distance and fixable there.

20. The retaining device (1) according to claim 18, wherein the receiving and retaining means (6) is embodied as elastic element (6f, 6g) for clamping the multimedia terminal (2).

21. The retaining device (1) according to claim 18, wherein the receiving and retaining means (6) is embodied as an elastic, casing (6h), and the multimedia-terminal (2) is adapted to be received in at least one of a force-fitting or form-fitting fashion in the elastic casing so that a display (2a) of the multimedia terminal (2) remains essentially unobstructed.
